(19) United States
(12) Patent Application Publication
(10) Pub. No.: US 2017/0213842 A1
(43) Pub. Date: Jul. 27, 2017

(54) SEMICONDUCTOR MEMORY DEVICE AND METHOD OF MANUFACTURING THE SAME

(71) Applicant: Samsung Electronics Co., Ltd., Suwon-si (KR)

(72) Inventors: Min-chul PARK, Hwaseong-si (KR); Bio KIM, Seoul (KR); Young-Gu KIM, Osan-si (KR); Jaehoon JEONG, Hwaseong-si (KR); Eunsuk CHO, Suwon-si (KR); Hyejin CHO, Hwaseong-si (KR); Jong In YUN, Seoul (KR)

(21) Appl. No.: 15/067,855

(22) Filed: Mar. 11, 2016

(30) Foreign Application Priority Data
Jan. 22, 2016 (KR) 10-2016-0008022

(51) Int. Cl. H01L 27/115; H01L 29/06; H01L 21/02; H01L 29/10; H01L 21/28

(52) U.S. Cl. CPC H01L 27/11582; H01L 29/1037; H01L 21/28282; H01L 21/02238; H01L 21/02164; H01L 29/0603

(57) ABSTRACT

A semiconductor memory device includes a substrate, a stack disposed on the substrate, a vertical channel structure penetrating the stack, and a fixed charge layer disposed in the vertical channel structure. The stack includes insulating patterns and gate electrodes alternately and repeatedly disposed on one another. The vertical channel structure includes a data storing pattern.

### CROSS-REFERENCE TO RELATED APPLICATION

This application claims priority from and the benefit of Korean Patent Application No. 10-2016-0008022, filed on Jan. 22, 2016, which is hereby incorporated by reference for all purposes as if fully set forth herein.

### BACKGROUND

Field

Exemplary embodiments relate to a semiconductor memory device and a method of manufacturing the same, and, more particularly, to a vertical-type semiconductor memory device and a method of manufacturing the same.

Discussion

Vertical-type semiconductor memory devices, such as V-NAND devices, may include memory cells and insulating layers disposed in a vertical direction with respect to a surface of a substrate. Such a configuration may increase the memory cell integration over that provided in a planar-type semiconductor memory device. In this manner, a vertical-type semiconductor memory device may include gate lines and insulating layers alternatively and repeatedly disposed on one another to form a stack enclosing a vertical channel extending from an upper surface of a substrate. When, however, the number of memory cells increases, a distance between adjacent memory cells decreases, and, as such, product reliability may deteriorate as a result of coupling effects between the adjacent memory cells, or the like.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide vertical-type semiconductor memory devices with improved electrical characteristics and methods of manufacturing the same.

Additional aspects will be set forth in the detailed description which follows, and, in part, will be apparent from the disclosure, or may be learned by practice of the inventive concept.

According to one or more exemplary embodiments, a semiconductor memory device includes a substrate, a stack disposed on the substrate, a vertical channel structure penetrating the stack, and a fixed charge layer disposed in the vertical channel structure. The stack includes insulating patterns and gate electrodes alternately and repeatedly disposed on one another. The vertical channel structure includes a data storing pattern.

According to one or more exemplary embodiments, a method of manufacturing a semiconductor memory device includes forming a stack on a substrate, forming a vertical channel structure penetrating the stack, and forming a fixed charge layer in the vertical channel structure. The stack includes insulating layers and gate electrodes alternately and repeatedly disposed on one another. The vertical channel structure includes a data storing pattern and a vertical channel pattern.

According to one or more exemplary embodiments, a semiconductor memory device includes vertically stacked memory cells including a common vertical channel, gate electrodes, and a layer. The common vertical channel includes a first region and a second region. The first region is disposed adjacent to the gate electrodes. The layer is disposed in the second region and is configured to counteract a capacitance between adjacent memory cells of the vertically stacked memory cells.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1A is a schematic plan view of a semiconductor memory device, according to one or more exemplary embodiments.

FIG. 1B is a cross-sectional view taken along sectional line I-I′ of the semiconductor memory device of FIG. 1A, according to one or more exemplary embodiments.

FIG. 1C is an enlarged view of an area A in FIG. 1B, according to one or more exemplary embodiments.

FIG. 2A is a schematic perspective view of a semiconductor memory device, according to one or more exemplary embodiments.

FIG. 2B is a cross-sectional view taken along sectional line II-IF of the semiconductor memory device of FIG. 2A, according to one or more exemplary embodiments.

FIG. 3 is a schematic view illustrating a short-channel effect from coupling between adjacent memory cells, according to one or more exemplary embodiments.

FIG. 4 is a cross-sectional view of a semiconductor memory device, according to one or more exemplary embodiments.

FIG. 5 is a cross-sectional view of a semiconductor memory device, according to one or more exemplary embodiments.

FIG. 6 is a cross-sectional view of a semiconductor memory device, according to one or more exemplary embodiments.

FIG. 7 is a cross-sectional view of a semiconductor memory device, according to one or more exemplary embodiments.

FIG. 8 is a schematic block diagram of a semiconductor device system including a semiconductor memory device, according to one or more exemplary embodiments.

FIG. 9 is a schematic block diagram of an electronic system including a semiconductor memory device, according to one or more exemplary embodiments.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

Unless otherwise specified, the illustrated exemplary embodiments are to be understood as providing exemplary features of varying detail of various exemplary embodiments. Therefore, unless otherwise specified, the features, components, elements, layers, films, panels, regions, and/or aspects of the various illustrations may be otherwise combined, separated, interchanged, and/or rearranged without departing from the disclosed exemplary embodiments. Further, in the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms “first,” “second,” etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

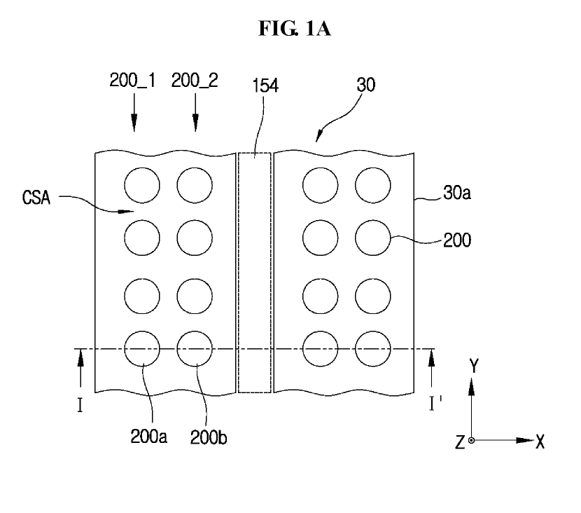

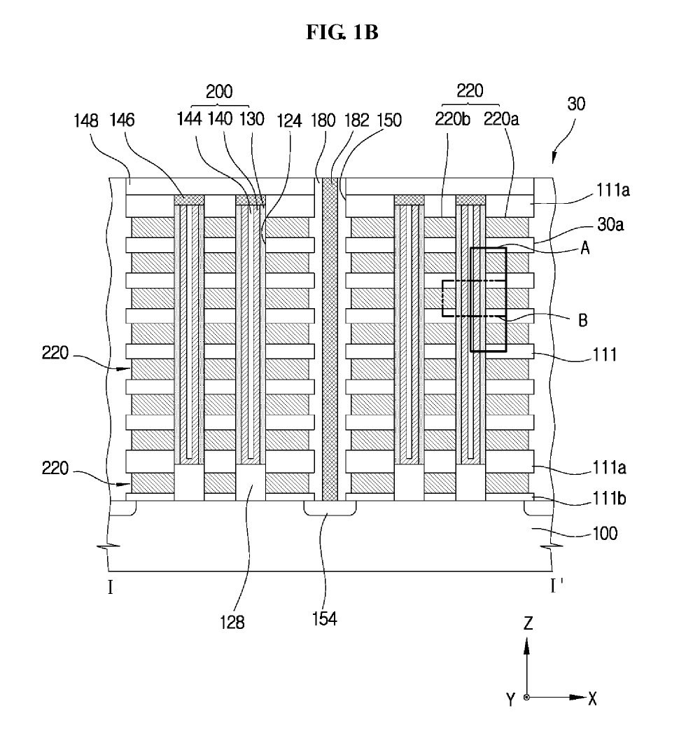

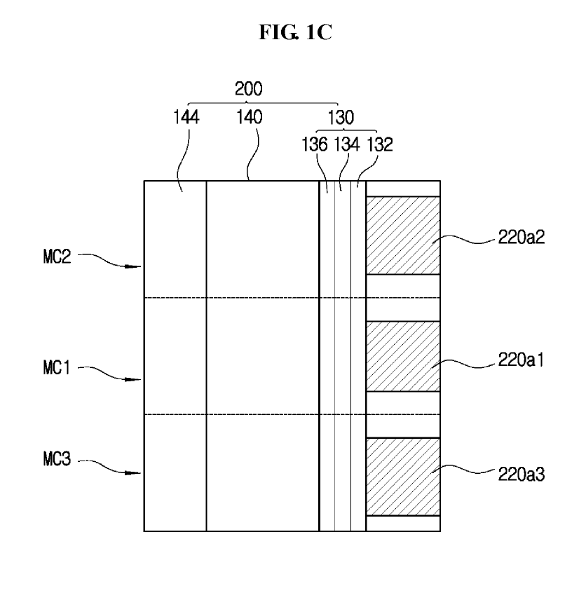

FIG. 1A is a schematic plan view of a semiconductor memory device, according to one or more exemplary embodiments. FIG. 1B is a cross-sectional view taken along sectional line I-I′ of the semiconductor memory device of FIG. 1A, according to one or more exemplary embodiments. FIG. 1C is an enlarged view of an area A in FIG. 1B, according to one or more exemplary embodiments.

Referring to FIGS. 1A, 1B, and 1C, a semiconductor memory device may include substrate 100, stack 30 disposed on substrate 100, and vertical channel structures 200 penetrating stack 30. Stack 30 may include insulating patterns 111 and gate electrodes 220 repeatedly and alternately disposed with one another. Vertical channel structures 200 may be disposed on a first surface (e.g., upper surface) of substrate 100 and may be spaced apart from one another in a first direction (e.g., x-direction). Vertical channel structures 200 may extend along a third direction (e.g., z-direction) perpendicular to the first surface. In this manner, the semiconductor memory device may define a vertical-type semiconductor memory device.

Substrate 100 may include a semiconductor material. For example, substrate 100 may be a single crystalline silicon wafer, a single crystalline germanium wafer, or a single crystalline silicon-germanium wafer. It is contemplated, however, that any suitable material or formation may be utilized in association with exemplary embodiments described herein. For instance, substrate 100 may be a semiconductor-on-insulator (SOI) wafer. For example, substrate 100 may include a semiconductor substrate, an insulating layer disposed on the semiconductor substrate to protect transistors formed thereon, and a semiconductor layer that may include silicon, silicon-germanium, or germanium. Substrate 100 may be doped to impart a first conductivity, e.g., p-type doping.

Stack 30 may have a line-shaped structure extending along a second direction (e.g., y-direction) intersecting the first direction. The first direction and the second direction may be parallel to the first surface of substrate 100. A thickness of insulating patterns 111 may be smaller than a thickness of gate electrodes 220. It is noted, however, that at least one of insulating patterns 111 may have a thickness greater than a thickness of gate electrodes 220. For instance, insulating patterns 111a disposed at a second lowermost row and at an uppermost row with respect to a vertical direction from substrate 100 may have a thickness greater than a thickness of gate electrodes 220. It is further noted that insulating patterns 111 and gate electrodes 220 may have the same thickness. It is also contemplated that insulating patterns 111b contacting substrate 100 may have a thickness smaller than a thickness of insulating patterns 111a disposed thereon. Insulating patterns 111 may include any suitable dielectric material, such as silicon oxide.

Vertical channel structures 200 may be electrically connected to substrate 100 through stack 30. Referring to FIG. 1A, vertical channel structures 200 may be arranged to form vertical channel structure array (CSA). In vertical channel structure array CSA, vertical channel structures 200 may be disposed along first column 200_1 and second column 200_2 in the second direction. Although two columns are illustrated, stack 30 may include any suitable number of columns. In the illustrated exemplary embodiment, first vertical channel structures 200a in first column 200_1 may be spaced apart from second vertical channel structures 200b in second column 200_2 in the first direction.

As shown in FIG. 1A, vertical channel structures 200 may be arranged in a matrix formation along the first direction and the second direction. It is contemplated, however, that any suitable formation may be utilized in association with exemplary embodiments described herein. For example, first vertical channel structures 200a may have translational symmetry with second vertical channel structures 200b with respect to an imaginary line extending along the first direction. Vertical channel structure arrays CSA may be repeatedly disposed along the first direction with common source region 154 disposed therebetween. As another example, vertical channel structures 200 may have a zigzag formation. To this end, first vertical channel structures 200a may not have translational symmetry with second vertical channel structures 200b. For instance, first vertical channel structures 200a may be shifted by half pitch in the second direction with respect to second vertical channel structures 200b.

Although not illustrated, vertical channel structures 200 may further include third vertical channel structures and fourth vertical channel structures. The third vertical channel structures and the fourth vertical channel structures may be respectively disposed along a third column and a fourth column adjacent to one another in the first direction. It is contemplated, however, that any suitable formation of vertical channel structure 200 may be utilized in association with exemplary embodiments described herein. For example, first vertical channel structures 200a may have translational symmetry with the third vertical channel structures, and second vertical channel structures 200b may have translational symmetry with the fourth vertical channel structures.

Vertical channel structures 200 may penetrate gate electrodes 220. Each gate electrode 220 may partially enclose at least one vertical channel structure 200. Each vertical channel structure 200 may include semiconductor pattern 128 disposed on substrate 100. Semiconductor pattern 128 may contact substrate 100 and may have a pillar shape extending upward from substrate 100. Semiconductor pattern 128 may include a doped or undoped semiconductor material. For example, semiconductor pattern 128 may be an epitaxial layer including single crystalline silicon.

Each vertical channel structure 200 may include data storing pattern 130, vertical channel pattern 140, and insulating gap-filling pattern 144. Vertical channel structures 200 may be formed in channel hole 124. Vertical channel pattern 140 may be disposed between data storing pattern 130 and insulating gap-filling pattern 144. Vertical channel pattern 200 may form a hollow tube, e.g., a hollow cylinder. It is contemplated, however, that any vertical channel pattern 140 may form any suitable polyhedral or annular polyhedral structure. For example, vertical channel pattern 140 may have a pipe-like shape with open top and bottom ends. As another example, vertical channel pattern 140 may have a solid circular cylinder shape. Vertical channel pattern 140 may include a semiconductor material having a poly-crystalline or amorphous crystal structure. For example, vertical channel pattern 140 may include silicon (Si), germanium (Ge), or a mixture thereof. It is also contemplated that vertical channel pattern 140 may include undoped semiconductor material.

Data storing pattern 130 may be disposed between stack 30 and vertical channel pattern 140. Data stored in data storing pattern 130 may be changed according to a Fowler-Nordheim tunneling effect, which may occur when a voltage difference exists between vertical channel structure 200 and gate electrodes 220. It is also contemplated that data storing pattern 130 may include a thin-film structure configured to change data stored therein. The thin-film structure may operate according to different principles than the Fowler-Nordheim tunneling effect. For instance, data storing pattern 130 may include a thin-film structure embodying a phase-change memory device or a variable-resistance memory device.

Referring to FIG. 1C, data storing pattern 130 may include blocking insulating layer 132 adjacent to vertical channel pattern 140, tunnel insulating layer 136 adjacent to vertical channel pattern 140, and charge storing layer 134 disposed between blocking insulating layer 132 and tunnel insulating layer 136.

Tunnel insulating layer 136 may be, for example, a silicon oxide layer. Charge storing layer 134 may be a trap insulating layer or an insulating layer including conductive nano dots. The trap insulating layer may include, for example, a silicon nitride layer. Blocking insulating layer 132 may include a silicon oxide layer and/or a high-k dielectric layer, such as aluminum oxide and hafnium oxide. Blocking insulating layer 132 may have a single-layer structure or a multi-layered structure. For example, blocking insulating layer 132 may have a single-layer structure of silicon oxide. As another example, blocking insulating layer 132 may have a multi-layered structure including at least one of an aluminum oxide layer and/or a hafnium oxide layer.

Although not illustrated, a second blocking insulating layer may be disposed between insulating patterns 111 and gate electrodes 220. For example, the second blocking insulating layer may extend parallel to substrate 100, and be disposed on (e.g., cover) top and bottom surfaces and/or at least a portion of side surfaces of gate electrodes 220. The second blocking insulating member may have a single-layer structure or a multi-layered structure. For example, the second blocking insulating member may include a high-k dielectric layer, such as aluminum oxide and hafnium oxide.

Insulating gap-filling pattern 144 may fill a gap region of vertical channel structure 200. Insulating gap-filling pattern 144 may include a silicon oxide layer or a silicon nitride layer. Conductive pads 146 may be disposed in each vertical channel structure 200, and may include any suitable conductive material. It is also contemplated that conductive pads 146 may be doped with impurities. End portions of vertical channel structures 200 in contact with conductive pads 146 may be drain regions. Conductive pads 146 may be connected to corresponding bit lines (not illustrated) disposed thereon. Cap insulating layer 148 may be disposed on conductive pad 146 and the uppermost insulating pattern 111.

Gate electrodes 220 may be control gate electrodes of memory cells in a vertical-type semiconductor memory device (e.g., a vertical-type NAND FLASH memory device). For example, a portion of gate electrodes 220 may be word lines of a vertical-type semiconductor memory device. For instance, gate electrodes 220 disposed between the uppermost and the lowermost gate electrodes 220 may be word lines. Vertical channel structures 200, the uppermost gate electrodes 220, and the lowermost gate electrodes 220 may form memory cell strings including memory cells disposed along the third direction.

For example, with reference to FIG. 1C, three gate electrodes 220a1, 220a2, and 220a3 may be respective word lines of memory cells MC1, MC2, and MC3 formed along the third direction. It is noted that FIG. 1C illustrates a first (e.g., right)-half of three adjacent memory cells MC1, MC2, and MC3. As shown in area B of FIG. 1B, each memory cell MC may include vertical channel structure 200 and gate electrode regions 220a and 220b enclosing vertical channel structure 200. [0050] The uppermost gate electrodes 220 and the lowermost gate electrodes 220 may be gate electrodes of selection transistors. For example, the uppermost gate electrode 220 may be used as a gate electrode of a string selection transistor SST controlling an electric connection between a corresponding bit line and each vertical channel structure 200. The lowermost gate electrode 220 may be used as a gate electrode of a ground selection transistor GST controlling an electric connection between each vertical channel structure 200 and common source region 154.

Each gate electrode 220 may include first region 220a adjacent to an outer portion of vertical channel structure 200 and second region 220b adjacent to an inner portion of vertical channel structure 200. For example, first region 220a of gate electrode 220 may be disposed between sidewall 30a of stack 30 and vertical channel structure 200, and second region 220b of gate electrode 220 may be disposed between adjacent vertical channel structures 200.

Common source region 154 may be disposed in substrate 100 between adjacent stacks 30. For example, trench 150 may be formed between stacks 30 and extend parallel to the second direction. Common source region 154 may be formed in a portion of substrate 100 exposed by trench 150. Common source region 154 may include an impurity region, which may be doped with, for example, a second conductivity type (e.g., n-type doping) different from that of substrate 100. Common source region 154 may include a silicide layer provided on the impurity region.

Source via plug 182 may be disposed on common source region 154 and in trench 150. Source via plug 182 may be connected to common source region 154, and, thus, electric resistance of common source region 154 may be reduced. Source via plug 182 may include island-shaped patterns disposed along the second direction or may have a line-shaped pattern extending parallel to the second direction. Source via plug 182 may include conductive material, such as metallic materials (e.g., tungsten). Insulating separation layer 180 may be disposed between sidewall 30a of stack 30 and source via plug 182. Insulating separation layer 180 may fill a gap region in trench 150 between insulating patterns 111, and, as such, may protect side surfaces of gate electrodes 220.

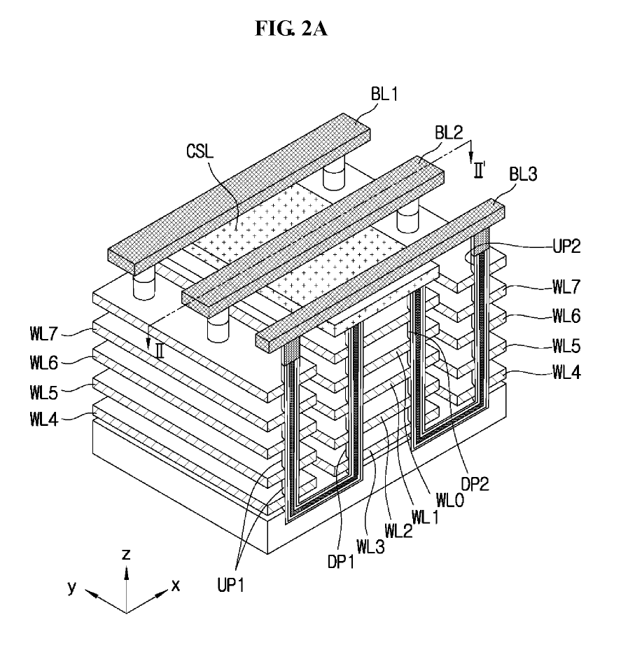

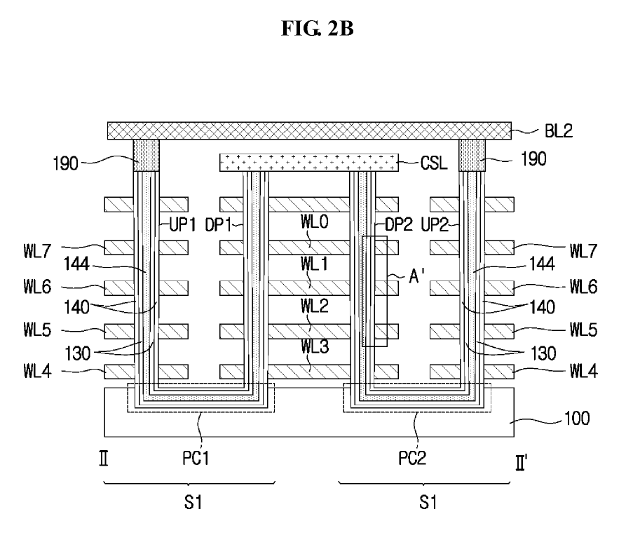

FIG. 2A is a schematic plan view of a semiconductor memory device, according to one or more exemplary embodiments. FIG. 2B is a cross-sectional view taken along sectional line II-IF of the semiconductor memory device of FIG. 2A, according to one or more exemplary embodiments.

Referring to FIGS. 2A and 2B, a semiconductor memory device according to one or more exemplary embodiments may include substrate 100. Word lines WL4, WL5, WL6, and WL7 extending in y-direction and spaced apart from one another may be sequentially disposed on substrate 100 along z-direction. First upper vertical channel structures UP1 and second upper vertical channel structures UP2 may be disposed sequentially in y-direction to penetrate word lines WL4, WL5, WL6, and WL7 in z-direction. Hereinafter, word lines WL4, WL5, WL6, and WL7 may be referred to as upper word lines.

Word lines WL0, WL1, WL2, and WL3 extending in y-direction and spaced apart from one another may be sequentially disposed on substrate 100 along z-direction. First lower vertical channel structures DP1 and second lower vertical channel structures DP2 may be sequentially disposed in y-direction to penetrate words lines WL0, WL1, WL2, and WL3 in z-direction. For example, first lower vertical channel structures DP1 and second lower vertical channel structures DP2 may be disposed in parallel along z-direction. Hereinafter, words lines WL0, WL1, WL2, and WL3 may be referred to as lower word lines.

Common source line CSL extending in y-direction may be disposed on first and second lower vertical channel structures DP1 and DP2. Common source line CSL may include, for example, n-type silicon. As another example, when common source line CSL includes metal or a non-polar conductive material such as polysilicon, n-type sources may be additionally disposed between common source line CSL and first and second lower vertical channel structures DP1 and DP2. Common source line CSL and first and second lower vertical channel structures DP1 and DP2 may be connected via contact plugs, respectively.

Drains 190 may be disposed on first and second upper vertical channel structures UP1 and UP2, respectively. Drains 190 may include, for example, n-type silicon. Bit lines BL1, BL2, and BL3 extending in x-direction may be disposed sequentially on drains 190 along y-direction. Bit lines BL1, BL2, and BL3 may be respectively connected to drains 190 via contact plugs.

First and second upper vertical channel structures UP1 and UP2 may respectively include data storing pattern 130, vertical channel pattern 140, and insulating gap-filling pattern 144. First and second lower vertical channel structures DP1 and DP2 may respectively include data storing pattern 130, vertical channel pattern 140, and insulating gap-filling pattern 144. For descriptive convenience, data storing pattern 130, vertical channel pattern 140, and insulating gap-filling pattern 144 may have substantially similar elements and configurations as those illustrated in FIG. 2B, and, as such, repeated description of similar elements will be omitted to avoid obscuring exemplary embodiments described herein.

First upper vertical channel structures UP1 and first lower vertical channel structures DP1 may be connected via first pipeline contacts PC1, respectively. For example, data storing pattern 130 and vertical channel pattern 140 of first upper vertical channel structures UP1 may be connected to data storing pattern 130 and vertical channel pattern 140 of first lower vertical channel structures DP1 via data storing pattern 130 and vertical channel pattern 140 of first pipeline contacts PC1, respectively. Data storing pattern 130 and vertical channel pattern 140 of first pipeline contacts PC1 may include the same material as those of data storing pattern 130 and vertical channel pattern 140 of first upper and lower vertical channel structures UP1 and DP1, respectively. Insulating gap-filling pattern 144 of first upper vertical channel structures UP1 may be connected to insulating gap-filling pattern 144 of first lower vertical channel structures DP1 via insulating gap-filling pattern 144 of first pipeline contacts PC1. Insulating gap-filling pattern 144 of first pipeline contacts PC1 may include the same material as that of insulating gap-filling pattern 144 of first upper and lower vertical channel structures UP1 and DP1.

First upper vertical channel structures UP1 and word lines WL4, WL5, WL6, and WL7 may form first upper strings, and first lower vertical channel structures DP1 and word lines WL0, WL1, WL2, and WL3 may form first lower strings. The first upper strings and the first lower strings may be connected to one another via first pipeline contacts PC1, respectively. Drains 190 and bit lines BL1, BL2, and BL3 may be connected to one ends of the first upper strings. Common source line CSL may be connected to one ends of the first lower strings. The first upper strings and the first lower strings may be connected to one another via first pipeline contacts PC1, and form strings S1 connected to common source line CLS and bit lines BL1, BL2, and BL3.

Second upper vertical channel structures UP2 and word lines WL4, WL5, WL6, and WL7 may form second upper strings, and second lower vertical channel structures DP2 and word lines WL0, WL1, WL2, and WL3 may form second lower strings. The second upper strings and the second lower strings may be connected to one another via second pipeline contacts PC2, respectively. Drains 190 and bit lines BL1, BL2, and BL3 may be connected to one ends of the second upper strings. Common source line CSL may be connected to one ends of the second lower strings. The second upper strings and the second lower strings may be connected to one another via second pipeline contacts PC2, and form strings S2 connected to common source line CLS and bit lines BL1, BL2, and BL3.

First pipeline contact gates (not shown) and second pipeline contact gates (not shown) may be formed in vertical channel patterns 140 of first pipeline contacts PC1 and second pipeline contacts PC2, respectively, to form a channel therein.

Area A′ of FIG. 2B may correspond to area A of FIG. 1B, which illustrates a first (e.g., right)-half of three adjacent memory cells. Constituting elements and configurations of area A′ of FIG. 2B may be substantially similar to those of area A of FIG. 1B, and, as such, for descriptive convenience, repeated description of similar elements will be omitted to avoid obscuring exemplary embodiments described herein.

As a degree of integration and a level of capacity of a vertical-type semiconductor memory device increases, the number of memory cells formed may increase, which may reduce a distance between adjacent memory cells MC1, MC2, and MC3. Shortened distance between memory cells may generate a coupling effect between the memory cells. The coupling effect may deteriorate the reliability of a vertical-type semiconductor memory device.

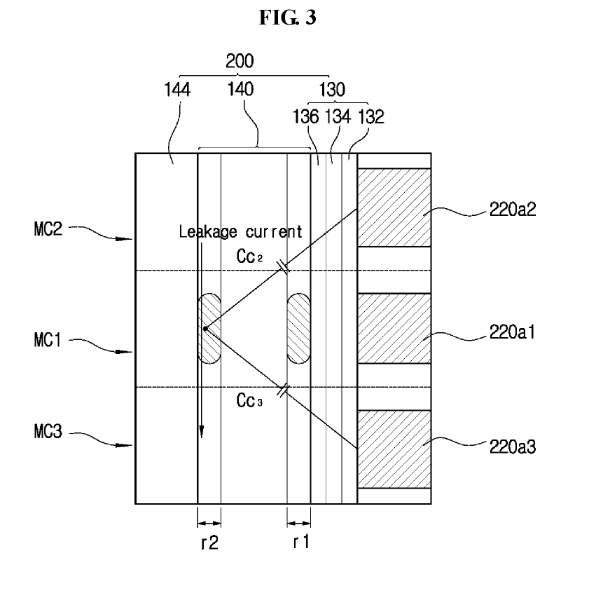

FIG. 3 a schematic view illustrating a short-channel effect (SCE) from coupling between adjacent memory cells, according to one or more exemplary embodiments. For descriptive convenience, the SCE will be described with reference to the same area of FIG. 1C (e.g., area A of FIG. 1B), and, thus, repeated description of similar elements will be omitted.

Hereinafter, executing a read operation on first memory cell MC1 will be described with reference to FIG. 3. Low-level voltage (for example, −1.5V) may be applied to first gate electrode 220a1 (e.g., a first word line), and high-level voltage (for example, 7V) may be applied to second gate electrode 220a2 and third gate electrode 220a3 (e.g., second and third word lines) corresponding to adjacent memory cells MC2 and MC3, respectively. It is noted that vertical channel pattern 140 may include undoped silicon, which may not include impurities. Vertical channel pattern 140 may include first region r1 adjacent to gate electrodes 220a1, 220a2, and 220a3, and second region r2 adjacent to insulating gap-filling pattern 144.

When the high-level voltage is applied to second gate electrode 220a2 and third gate electrode 220a3, a channel may be formed in vertical channel patterns 140 of second memory cell MC2 and third memory cell MC3. In this manner, second memory cell MC2 and third memory cell MC3 may be turned on, regardless of a threshold voltage of second memory cell MC2 and third memory cell MC3.

When the low-level voltage is applied to first gate electrode 220a1, a channel may be selectively formed in vertical channel pattern 140 of first memory cell MC1, depending on the threshold voltage of first memory cell MC1. In this manner, first memory cell MC1 may be turned on or turned off according to the threshold voltage of first memory cell MC1. Hereinafter, an example in which first memory cell MC1 is turned off by the low-level voltage applied to first gate electrode 220a1 will be described in more detail with reference to FIG. 3.

As first memory cell MC1 is turned off, a channel (or a current path) may not be formed in vertical channel pattern 140 of first memory cell MC1. Since first region r1 of vertical channel pattern 140 of first memory cell MC1 is adjacent to first gate electrode 220a1, first region r1 may be controlled by the voltage applied to first gate electrode 220a1. Second region r2, however, may not be stably controlled by the voltage applied to first gate electrode 220a1, as second region r2 is disposed at a distance from first gate electrode 220a1. In other words, because electrons in vertical channel pattern 140 of first memory cell MC1 exist across first region r1 and second region r2, second region r2 disposed at the distance from first gate electrode 220a1 may not be stably controlled by the voltage applied to first gate electrode 220a1.

For instance, second region r2 of vertical channel pattern 140 of first memory cell MC1 may be affected by the low-level voltage applied to first gate electrode 220a1 and the high-level voltage applied to second gate electrode 220a2 and third gate electrode 220a3 of adjacent memory cells MC2 and MC3. In this manner, capacitances C_{c2} and C₃ may be respectively formed between second region r2 and second gate electrode 220a2 and third gate electrode 220a3. Accordingly, second region r2 may be positively charged (for example, 0.35V) by capacitances C_{c2} and C_{c3}. Thus, a channel (or a current path) may be formed in second region r2 of vertical channel pattern 140 of first memory cell MC1, and, as such, leakage current may be generated.

As described above, a distance between adjacent memory cells MC1, MC2, and MC3 may be short in vertical-type semiconductor memory devices. Accordingly, when high-level voltage is applied to second gate electrode 220a2 and third gate electrode 220a3 of adjacent memory cells MC2 and MC3, current may leak in second region r2 of vertical channel pattern 140 of first memory cell MC1 (or around an interface between vertical channel pattern 140 and insulating gap-filling pattern 144). The leakage current may deteriorate the reliability of the vertical-type semiconductor memory device.

According to one or more exemplary embodiments, a negative fixed charge layer having a negative charge may be disposed in vertical channel structure 200 to prevent (or at least reduce) current leakage in second region r2 of vertical channel pattern 140.

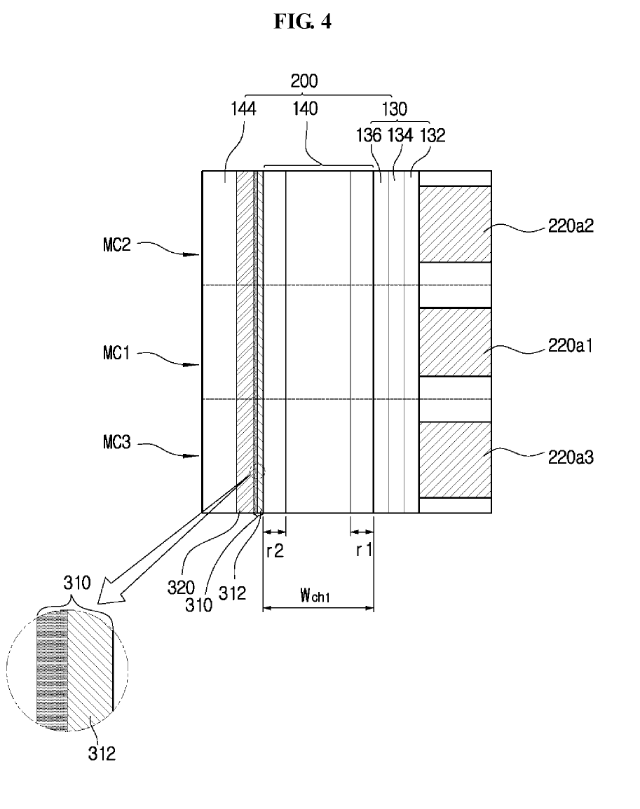

FIGS. 4, 5, 6, and 7 illustrate cross-sectional views of semiconductor memory devices, according to one or more exemplary embodiments. For descriptive convenience, semiconductor memory devices illustrated in FIGS. 4, 5, 6, and 7 correspond to the same area of FIG. 1C (e.g., area A of FIG. 1B), and, as such, repeated description of similar elements will be omitted to avoid obscuring exemplary embodiments described herein.

Referring to FIG. 4, a vertical-type semiconductor memory device may include silicon oxide layer 310 disposed on an interface of second region r2 of vertical channel pattern 140, and metal oxide layer 320 disposed on an interface of silicon oxide layer 310. Silicon oxide layer 310 and metal oxide layer 320 may be disposed between vertical channel pattern 140 and insulating gap-filling pattern 144.

Silicon oxide layer 310 may be formed by an oxidization process on an interface of second region r2 of vertical channel pattern 140. For example, an oxidizing agent, such as oxygen, may be applied to a surface of vertical channel pattern 140 formed with silicon. The oxidizing agent may substitute silicon by disconnecting the atomic bonding of the silicon. Metal oxide layer 320 may be formed by a deposition process on an interface of silicon oxide layer 310. For example, metal oxide layer 320 may include aluminum oxide.

According to one or more exemplary embodiments, processes for forming silicon oxide layer 310 and metal oxide layer 320 may be performed between processes forming vertical channel pattern 140 and insulating gap-filling pattern 144. For example, when metal oxide layer 320 includes aluminum oxide, aluminum may pass through silicon oxide layer 310 and penetrate into vertical channel pattern 140, depending on thermal processing conditions. In this manner, metal atoms, such as aluminum, may be activated by heat generated from at least one semiconductor manufacturing process and penetrate into vertical channel pattern 140. The aluminum atoms may bond with an atom in a dangling bond state (for example, a silicon atom or an silicon oxide atom) in an interface between silicon oxide layer 310 and vertical channel pattern 140. When the aluminum atom bonds with the atom in the dangling bond state, a layer fixed with negative charge (e.g., negative fixed charge layer 312) may be formed on an interface of silicon oxide layer 310 in contact with vertical channel pattern 140.

According to one or more exemplary embodiments, metal oxide layer 320 may include at least one of aluminum oxide (Al₂O₃), hafnium oxide (HfO₂), tantalum pentoxide (Ta₂O₅), zirconium oxide (ZrO₂), titanium oxide (TiO), lanthanum oxide (La₂O₃), praseodymium oxide (PrO₂), cerium oxide (CeO₂), neodymium oxide (Nd₂O₃), promethium oxide (Pm₂O₃), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (HO₂O₃), erbium oxide (Er₂O₃), thulium oxide (Tm₂O), ytterbium oxide (Yb₂O), lutetium oxide (Lu₂O₃), yttrium oxide (Y₂O), hafnium nitride (HfN), aluminum nitride (AlN), hafnium oxynitride (HfON), aluminum oxynitride (AlON).

As described above, when a read operation is executed with respect to first memory cell MC1, second gate electrode 220a2 and third gate electrode 220a3 of adjacent memory cells MC2 and MC3 may generate a coupling effect. The coupling effect may generate a positive charge (for example, 0.35V) in second region r2. According to one or more exemplary embodiments, negative charge formed in negative fixed charge layer 312 may offset the positive charge formed in second region r2. In other words, negative fixed charge layer 312 may prevent (or at least reduce) current leakage in second region r2 of vertical channel pattern 140.

The negative charge formed on negative fixed charge layer 312 may push evenly distributed electrons in vertical channel pattern 140 towards first region r1 of vertical channel pattern 140. In this manner, electrons in vertical channel pattern 140 may be confined in first region r1, thereby reducing a channel width. As such, a short-channel effect (SCE), for example, drain induced barrier lowering (DIBL), may be improved. In other words, an effective channel width of vertical channel pattern 140 may be narrower than actual channel width Wₐₗₗ.

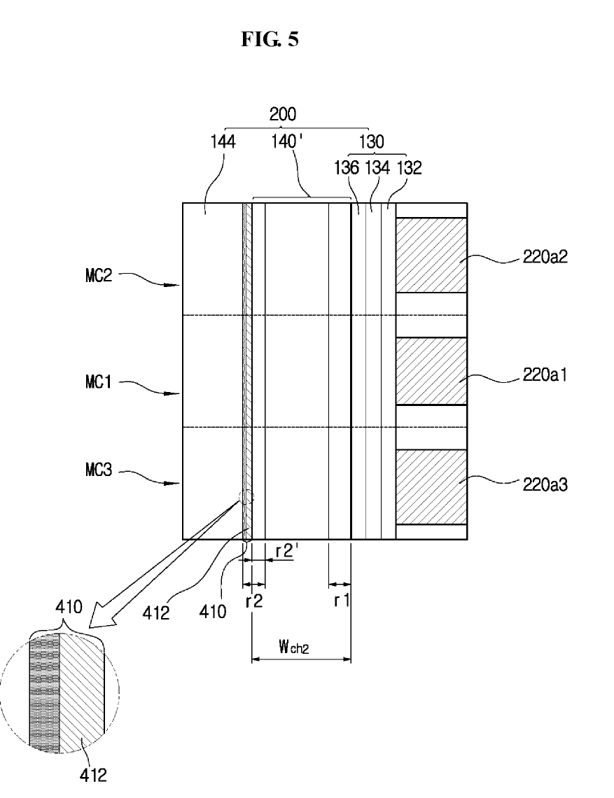

Adverting to FIG. 5, an interface of second region r2 of vertical channel pattern 140′ layer may be doped to form doping layer 410. For example, as a p-type dopant, Group III elements (such as boron), may be doped in second region r2, resulting in doping layer 410 of a p-type. As a portion of second region r2 is doped to form doping layer 410, the width of vertical channel pattern 140′ may be reduced by the width of doping layer 410. For instance, width W_{ch2} of vertical channel pattern 140′ may be smaller than width W_{ch1} of vertical channel pattern 140 of FIG. 4. Furthermore, since a portion of second region r2 is formed as doping layer 410, the width of second region r2′ may become smaller.

Electron affinity of p-type doping layer 410 may be increased as, for instance, doped boron atoms may serve as an acceptor. For example, when current flows from a source region to a drain region of vertical channel pattern 140′ in each memory cell MC1, MC2, and MC3, the boron atoms in p-type doping layer 410 may accept electrons, thereby forming a space charge. The space charge may be formed in an interface of second region r2′ of vertical channel pattern 140′. In this manner, the space charge may serve as a layer fixed with negative charge, thereby forming negative fixed charge layer 412.

As described above, when a read operation is executed with respect to first memory cell MC1, second gate electrode 220a2 and third gate electrode 220a3 of adjacent memory cells MC2 and MC3 may generate a coupling effect. The coupling effect may generate positive charge (for example, 0.35V) in second region r2. According to one or more exemplary embodiments, a negative charge formed in negative fixed charge layer 412 may offset the positive charge formed in second region r2′. In other words, negative fixed charge layer 412 may prevent (or at least reduce) a current leakage in second region r2′.

The negative charge formed on negative fixed charge layer 412 may push evenly distributed electrons in vertical channel pattern 140′ towards first region r1 of vertical channel pattern 140′. In this manner, electrons in vertical channel pattern 140′ may be confined in first region r1, thereby reducing a channel width. As such, a short-channel effect (SCE), for example, drain induced barrier lowering (DIBL), may be improved. In other words, in vertical channel pattern 140′, an effective channel width may be narrower than actual channel width W_{ch2}.

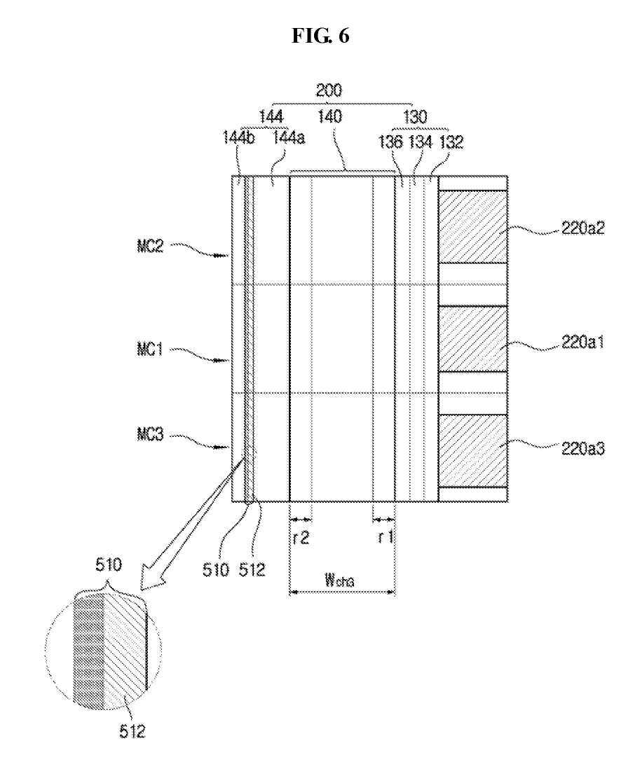

With reference to FIG. 6, doping layer 510 may be formed in insulating gap-filling pattern 144. Hereinafter, a method of forming doping layer 510 as part of fabricating a semiconductor memory device will be described in more detail with reference to FIGS. 1B and 6.

Referring back to FIG. 1B, in vertical channel structure 200 formed in channel hole 124, data storing pattern 130 and vertical channel pattern 140 may be sequentially formed in channel hole 124. First insulating gap-filling pattern 144a may be formed on an interface of vertical channel pattern 140. An interface of first insulating gap-filling pattern 144a may be doped with impurities to form doping layer 510. For example, as a p-type dopant, Group III elements (such as boron), may be doped in first insulating gap-filling pattern 144a, resulting in doping layer 510 of a p-type. Second insulating gap-filling pattern 144b may be formed to fill vertical channel structure 200. First insulating gap-filling pattern 144a and second insulating gap-filling pattern 144b may include silicon oxide or silicon nitride.

Electron affinity of p-type doping layer 510 may be increased as, for instance, doped boron atoms may serve as an acceptor. For example, the boron atoms in p-type doping layer 510 may accept electrons provided during fabrication of the semiconductor memory device. This may form a space charge. The space charge may be formed adjacent to second region r2 of vertical channel pattern 140 in a fixed manner. To this end, the space charge may serve as a layer fixed with negative charge, thereby forming negative fixed charge layer 512.

As described above, when a read operation is executed with respect to first memory cell MC1, second gate electrode 220a2 and third gate electrode 220a3 of adjacent memory cells MC2 and MC3 may generate a coupling effect. The coupling effect may generate positive charge (for example, 0.35V) in second region r2. According to one or more exemplary embodiments, the negative charge formed in negative fixed charge layer 512 may offset the positive charge formed in second region r2. In other words, negative fixed charge layer 512 may prevent (or at least reduce) current leakage in second region r2.

The negative charge formed on negative fixed charge layer 512 may push evenly distributed electrons in vertical channel pattern 140 towards first region r1 of vertical channel pattern 140. In this manner, electrons in vertical channel pattern 140 may be confined in first region r1, thereby reducing a channel width. As such, a short-channel effect (SCE), for example, drain induced barrier lowering (DIBL), may be improved. In other words, in vertical channel pattern 140, an effective channel width may be narrower than actual channel width W_{ch3}.

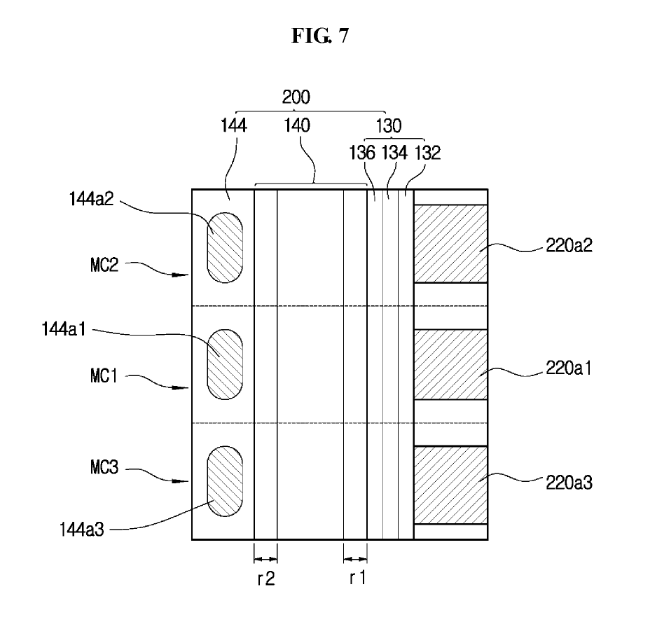

With reference to FIG. 7, a vertical-type semiconductor memory device may include air layers 144a in insulating gap-filling pattern 144. Air layers 144a may be formed to correspond to memory cells MC1, MC2, and MC3. For example, first air layer 144a1 may be formed in insulating gap-filling pattern 144 of first memory cell MC1, second air layer 144a2 may be formed in insulating gap-filling pattern 144 of second memory cell MC2, and third air layer 144a3 may be formed in insulating gap-filling pattern 144 of third memory cell MC3. First, second, and third air layers 144a1, 144a2, and 144a3 may be spaced apart from one another.

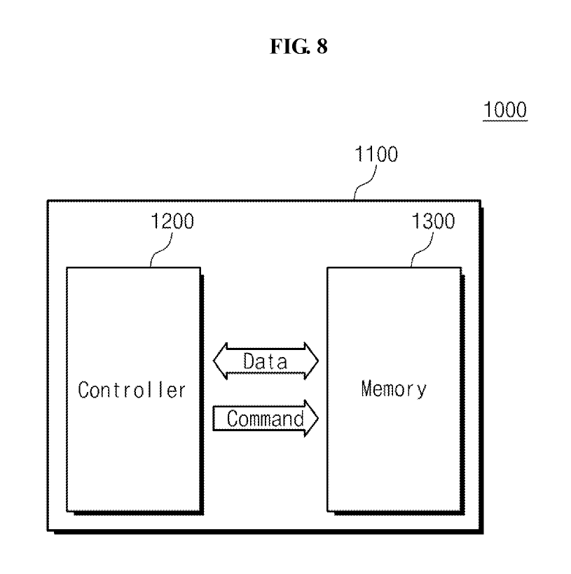

FIG. 8 is a schematic block diagram of a semiconductor memory system including a semiconductor memory device, according to one or more exemplary embodiments.

Referring to FIG. 8, memory system 1000 may be configured to store data in at least one semiconductor device. For example, memory system 1000 may be provided in the form of a memory card or a solid state drive (SSD). Memory system 1000 may include controller 1200 and memory device 1300 provided in housing 1100. Memory system 1000 may be configured to allow electric signals to be exchanged between controller 1200 and memory device 1300. For example, an operation of exchanging data between memory device 1300 and controller 1200 may be executed in response to commands from controller 1200. In other words, memory system 1000 may be configured to store data in memory device 1300 to the outside thereof. Memory device 1300 may include one or more semiconductor memory devices according to one or more of the exemplary embodiments described herein.

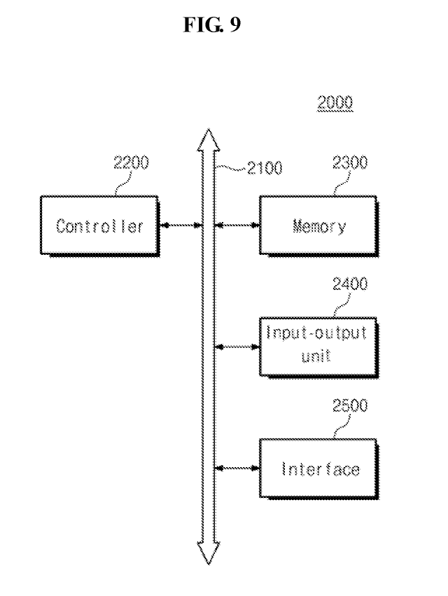

FIG. 9 is a schematic block diagram of an electronic system including a semiconductor memory device, according to one or more exemplary embodiments.

Referring to FIG. 9, electronic system 2000 may include controller 2200, memory device 2300, and input-output unit 2400. Controller 2200, memory device 2300, and input-output unit 2400 may be electrically coupled or connected to each other via bus 2100. Bus 2100 may correspond to a path through which electrical signals or data are transmitted. Controller 2200 may include at least one of a microprocessor, a digital signal processor, a microcontroller, or a logic device. The logic device may have a similar function to any one of the microprocessor, the digital signal processor, and the microcontroller. Input-output unit 2400 may include at least one of a keypad, a keyboard, or a display device. Memory device 2300 may store data and/or commands executed by controller 2200. Memory device 2300 may include a volatile memory device and/or a nonvolatile memory device. For example, memory device 2300 may include a FLASH memory device. It is contemplated, however, that memory device 2300 may include a solid state drive (SSD) including at least one FLASH memory device. In this manner, electronic system 2000 may stably store a large capacity of data. According to one or more exemplary embodiments, memory device 2300 may include one or more semiconductor memory devices according to one or more of the exemplary embodiments described herein. Electronic system 2000 may further include interface unit 2500 for transmitting or receiving data to or from a communication network through a wireless or wired medium. For example, interface unit 2500 may include an antenna for wireless communication or a transceiver for wired communication.

According to one or more exemplary embodiments, semiconductor memory devices may be encapsulated using any suitable packaging technique. For example, a semiconductor memory device may be encapsulated using any one of a package on package (POP) technique, a ball grid array (BGA) technique, a chip scale package (CSP) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic quad flat package (PQFP) technique, a thin quad flat package (TQFP) technique, a small outline package (SOIC) technique, a shrink small outline package (SSOP) technique, a thin small outline package (TSOP) technique, a system in package (SIP) technique, a multi-chip package (MCP) technique, a wafer-level fabricated package (WFP) technique, and a wafer-level processed stack package (WSP) technique. The package in which the semiconductor memory device is mounted may further include at last one semiconductor device (e.g., a controller and/or a logic device) that controls the semiconductor memory device.

Although exemplary embodiments have been described with respect to a negative fixed charge layer, it is contemplated that the polarity of the fixed charge layer may be oppositely configured. As such, the configuration of one or more other features described herein, such as a polarity of the doping impurities, may be oppositely configured. For instance, the p-type impurities utilized to form doping layers 410 and 510 may be n-type impurities selected from, for instance, Group V and/or Group VI elements. In this manner, the negative fixed charge layer may be configured as a positive fixed charge layer.

According to one or more exemplary embodiments, a fixed charge layer may be formed in a vertical channel structure. A charge formed in the fixed charge layer may prevent (or at least reduce) current leakage in a vertical channel portion and improve electric characteristics of a semiconductor memory device from a short-channel effect.

Although certain exemplary embodiments and implementations have been described herein, other embodiments and modifications will be apparent from this description. Accordingly, the inventive concept is not limited to such exemplary embodiments, but rather to the broader scope of the presented claims and various obvious modifications and equivalent arrangements.

1. A semiconductor memory device, comprising:
a substrate;
a stack disposed on the substrate, the stack comprising insulating patterns and gate electrodes alternately and repeatedly disposed on one another;
a vertical channel structure penetrating the stack, the vertical channel structure comprising a data storing pattern;
a fixed charge layer disposed in the vertical channel structure; and
a metal oxide layer disposed in the vertical channel structure,
wherein the metal oxide layer is spaced apart from the fixed charge layer.

2. The semiconductor memory device of claim 1, wherein:
the vertical channel structure further comprises a vertical channel pattern; and
the vertical channel pattern comprises undoped silicon.

3. The semiconductor memory device of claim 2, wherein:
the vertical channel structure further comprises an insulating gap-filling pattern; and
the vertical channel pattern comprises:
a first region disposed adjacent to the gate electrodes; and
a second region disposed adjacent to the insulating gap-filling pattern.

4. The semiconductor memory device of claim 3, wherein the metal oxide layer is disposed in the second region.

5. The semiconductor memory device of claim 4, further comprising:
a silicon oxide layer disposed on an interface of the second region, the silicon oxide layer being disposed between the metal oxide layer and the fixed charge layer.

6. The semiconductor memory device of claim 5, wherein the fixed charge layer comprises metal atoms of the metal oxide layer bonded with atoms in a dangling bond state at an interface of the silicon oxide layer.

7. The semiconductor memory device of claim 6, wherein the metal oxide layer comprises at least one of aluminum (Al), hafnium (Hf), tantalum (Ta), zirconium (Zr), titanium (Ti), lanthanum (La), praseodymium (Pr), cerium (Ce), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), yttrium (Y), hafnium nitride (HfN), aluminum nitride (AlN), hafnium oxynitride (HfON), and aluminum oxynitride (AlON).

8. The semiconductor memory device of claim 3, wherein a first interface of the second region comprises a dopant forming a doping layer in the vertical channel pattern.

9. The semiconductor memory device of claim 8, wherein:
a polarity of the doping layer is opposite a polarity of the fixed charge layer; and
the doping layer is configured to attract inflow electrons to form a space charge at a fixed position in a second interface of the second region to form the fixed charge layer.

10. The semiconductor memory device of claim 8, wherein a width of the vertical channel pattern is reduced by a width of the doping layer.

11. The semiconductor memory device of claim 3, wherein:
the insulating gap-filling pattern comprises:
a first insulating gap-filling pattern; and
a second insulating gap-filling pattern; and
the fixed charge layer is disposed between the first insulating gap-filling pattern and the second insulating gap-filling pattern.

12. The semiconductor memory device of claim 11, further comprising:
a doping layer disposed on a first interface of the first insulating gap-filling pattern.

13. The semiconductor memory device of claim 12, wherein:
a polarity of the doping layer is opposite a polarity of the fixed charge layer; and
the doping layer is configured to attract inflow electrons to form a space charge at a fixed position in a second interface of the second region to form the fixed charge layer.

14. A method of manufacturing a semiconductor memory device, the method comprising:
forming a stack on a substrate, the stack comprising insulating layers and gate electrodes alternately and repeatedly disposed on one another;
forming a vertical channel structure penetrating the stack, the vertical channel structure comprising a data storing pattern and a vertical channel pattern; and
forming a fixed charge layer in the vertical channel structure.

15. The method of claim 14, wherein forming the fixed charge layer comprises:
oxidizing an interface of the vertical channel pattern to form a silicon oxide layer; and
depositing metal on an interface of the silicon oxide layer to form a metal oxide layer.

16. The method of claim 15, wherein the metal oxide layer comprises at least one of aluminum (Al), hafnium (Hf), tantalum (Ta), zirconium (Zr), titanium (Ti), lanthanum (La), praseodymium (Pr), cerium (Ce), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), yttrium (Y), hafnium nitride (HfN), aluminum nitride (AlN), hafnium oxynitride e (HfON), and aluminum oxynitride (AlON)m.

17. The method of claim 14, wherein:
forming the fixed charge layer comprises doping an interface of the vertical channel pattern with p-type impurities; and
the vertical channel pattern comprises undoped silicon.

18. The method of claim 14, wherein:
the vertical channel structure further comprises an insulating gap-filling pattern; and
forming the fixed charge layer comprises:
doping an interface of the insulating gap-filling pattern with p-type impurities; and
filling a gap in the vertical channel structure with silicon oxide or silicon nitride.

19. A semiconductor memory device, comprising:
vertically stacked memory cells comprising a common vertical channel and gate electrodes, the common vertical channel comprising:
a first region adjacent to the gate electrodes;
a first insulating layer adjacent to the first region; and
a second region between the first insulating layer and the first region;
a second insulating layer in the second region; and
a layer directly on the second insulating layer, the second insulating layer being between the first insulating layer and the layer,
wherein the layer is configured to counteract a capacitance between adjacent memory cells of the vertically stacked memory cells.

20. The semiconductor memory device of claim 19, further comprising:
a metal oxide layer between the first insulating layer and the second insulating layer.
